(19) United States
(12) Patent Application Publication
(10) Pub. No.: US 2015/0302990 A1
(43) Pub. Date: Oct. 22, 2015

(54) MULTILAYER FILM INCLUDING FIRST AND SECOND DIELECTRIC LAYERS

(71) Applicant: 3M INNOVATIVE PROPERTIES COMPANY, Saint Paul, MN (US)

(72) Inventors: Dipankar Ghosh, Oakdale, MN (US); Christopher S. Lyons, St. Paul, MN (US); Robin E. Gorrell, Round Rock, TX (US); Stephen P. Maki, North St. Paul, MN (US)

(21) Appl. No.: 14/646,648

(22) PCT Filed: Nov. 21, 2013
(86) PCT No.: PCT/US2013/071192

§ 371 Date: May 21, 2015

Related U.S. Application Data
(60) Provisional application No. 61/728,986, filed on Nov. 21, 2012.
(60) Provisional application No. 61/779,906, filed on Mar. 13, 2013.

(51) Int. Cl. H01G 4/10; C23C 28/00; C23C 16/22; C25D 5/00; C23C 14/34; C23C 14/08

(52) U.S. Cl. CPC H01G 4/10; C23C 14/34; C23C 14/083; C23C 16/22; C25D 5/00; C23C 28/32; C23C 28/3455

(57) ABSTRACT

A multilayer dielectric film including a first dielectric layer made from a material having a first breakdown field strength and a second dielectric layer disposed on the first dielectric layer made from a material having a different breakdown filed strength. A multilayer film including first and second electrically conductive layers separated by at least first and second dielectric layers is also disclosed. The first dielectric layer is disposed on the first electrically conductive layer, and the second dielectric layer is disposed on the first dielectric layer. The first electrically conductive layer can have at least one of an average surface roughness of at least ten nanometers, a thickness of at least ten micrometers, or an average visible light transmission of up to ten percent. The first dielectric layer may be a polymer and typically has a lower dielectric constant than the second dielectric layer, which may be ceramic.

### CROSS REFERENCE TO RELATED APPLICATIONS

This application claims priority to U.S. Provisional Application Nos. 61/728,986, filed Nov. 21, 2012, and 61/779,906, filed Mar. 13, 2013, the disclosures of which are incorporated by reference in their entirety herein.

### BACKGROUND

In microelectronic products, typically about 80 percent of the electronic components belong to the passive component category, which are unable to add gain or perform switching functions in circuit performance. Surface-mounted discrete components can occupy over 40 percent of the printed circuit/wiring board surface area; taking up this amount of space can provide a challenge. Other challenges associated with discrete passives include cost, handling, assembly time, and yield.

Embedded passives provide an alternative to discrete passives. By removing discrete passive components from the surface of a printed circuit/wiring board and embedding them into the inner layers of substrate board, embedded passives can provide many advantages such as reduction in size and weight, improvement in reliability, better performance, and reduced cost. These advantages, for example, have driven a significant amount of effort during the past decade toward the development of embedded passives technology. See, for example, U.S. Pat. No. 6,974,547 (Kohara et al.) and U.S. Pat. No. 8,183,108 (Borland et al.) and U.S. Pat. Appl. Pub. Nos. 2007/0006435 (Banerji et al.) and 2010/0073845 (Suh et al.)

In other technologies, inorganic or hybrid inorganic/organic layers have been used in thin films for electrical, packaging, and decorative applications. These layers can provide desired properties such as mechanical strength, thermal resistance, chemical resistance, abrasion resistance, moisture barriers, and oxygen barriers. Multilayer structures can be prepared by a variety of production methods. These methods include liquid coating techniques such as solution coating, roll coating, dip coating, spray coating, and spin coating; and dry coating techniques such as Chemical Vapor Deposition (CVD), Plasma Enhanced Chemical Vapor Deposition (PECVD), sputtering, and vacuum processes for thermal evaporation of solid materials. One approach for multilayer coatings has been to produce multilayer oxide coatings, such as aluminum oxide or silicon oxide, interspersed with thin polymer film protective layers. Examples of multilayer constructions can be found in U.S. Pat. No. 7,449,146 (Rakow et al.) and U.S. Pat. Appl. Pub. No. 2009/0109537 (Bright et al.).

### SUMMARY

The next generations of embedded capacitors require higher capacitance densities with acceptable values of dielectric loss and leakage current for applications in microelectronics. Capacitance density can be increased by using thinner dielectric materials. However, low yield of functional capacitors can result when thin dielectric films are used because of substrate surface roughness, foreign particle contamination, and pinholes and cracks in the dielectric thin film.

The present disclosure provides multilayer films including first and second dielectric layers that can be useful, for example, in thin film capacitors for embedded capacitor and energy storage applications. The first dielectric layer on an electrically conductive substrate serves as a planarizing dielectric layer that can mitigate problems with surface roughness and foreign particle contamination. The second dielectric layer is disposed on (e.g., disposed directly on) the first dielectric layer. In many embodiments, the second dielectric layer can cover any cracks or pinholes that are formed in the first dielectric layer. The combination of first and second dielectric layers typically provides a high yield of functional capacitors on flexible substrates with high capacitance density values, low dielectric loss, and excellent insulating properties. Advantageously, the multilayer films disclosed herein do not require sophisticated deposition equipment, a clean room environment, or typically any kind of surface cleaning treatment of substrates.

In one aspect, the present disclosure provides multilayer dielectric film with a first dielectric layer including a first material having a first breakdown field strength and a second dielectric layer formed directly on the first dielectric layer and including a second material having a second breakdown field strength less than the first breakdown field strength. The first dielectric layer has a third breakdown field strength at a localized position that is less than the second breakdown field strength, and the multilayer dielectric film has a fourth breakdown field strength at the localized position that is greater than the third breakdown field strength. The localized position may be, for example, a crack or pinhole in the first dielectric layer.

In another aspect, the present disclosure provides a multilayer film including first and second electrically conductive layers separated by at least first and second dielectric layers. Typically, the first dielectric layer is disposed on the first electrically conductive layer, and the second dielectric layer is disposed on the first dielectric layer. In some embodiments, a second electrically conductive layer is atop the second dielectric layer. In some embodiments, there is a plurality of alternating first and second dielectric layers atop the second electrically conductive layer.

In one embodiment, the multilayer film includes first and second electrically conductive layers separated by at least first and second dielectric layers. The first dielectric layer is formed directly on the first electrically conductive layer by a condensation of a vaporized liquid, and the second dielectric layer is formed directly on the first dielectric layer. The second dielectric layer is not formed by a condensation of a vaporized liquid. The first and second electrically conductive layers have an average visible light transmission of less than about ten percent.

In another embodiment, the multilayer film includes first and second electrically conductive layers separated by at least first and second dielectric layers. The first electrically conductive layer has a surface with an average roughness of at least ten nanometers. The first dielectric layer is formed directly on the surface of the first electrically conductive layer and has a first dielectric constant. The second dielectric layer is formed directly on the first dielectric layer and has a second dielectric constant greater than the first dielectric constant.

In another embodiment, the multilayer film includes a first metal layer having a surface with an average surface roughness of at least ten nanometers, a first dielectric layer formed directly on the surface of the first metal layer and having a first dielectric constant less than 20, and a second dielectric layer formed directly on the first dielectric layer and having a second dielectric constant greater than 20. A second metal layer is electroplated as the uppermost layer in the multilayer film.

In another embodiment, the multilayer film includes a first electrically conductive layer having a thickness greater than ten micrometers, a first polymer layer formed directly on the surface of the first electrically conductive layer and having a thickness of less than one micrometer, and a ceramic layer formed directly on the polymer layer and having a thickness of less than one micrometer. A second electrically conductive layer atop at least the first electrically conductive layer and the first and second dielectric layers has a thickness greater than ten micrometers.

In another embodiment, the multilayer film includes first and second electrically conductive layers separated by at least first and second dielectric layers. The first dielectric layer is disposed on the surface of the first electrically conductive layer. The second dielectric layer is disposed on the first dielectric layer. The first dielectric layer includes a polymer, and the second dielectric layer includes a ceramic. The first electrically conductive layer has at least one of an average surface roughness of at least 10 nanometers or a thickness of at least 10 micrometers.

The present disclosure further provides use of a multilayer film as in any of the above embodiments as a capacitor.

In this application, terms such as “a”, “an” and “the” are not intended to refer to only a singular entity, but include the general class of which a specific example may be used for illustration. The terms “a”, “an”, and “the” are used interchangeably with the term “at least one”. The phrases “at least one of” and “comprises at least one of” followed by a list refers to any one of the items in the list and any combination of two or more items in the list. All numerical ranges are inclusive of their endpoints and non-integral values between the endpoints unless otherwise stated.

The terms “first” and “second” are used in this disclosure in their relative sense only. It will be understood that, unless otherwise noted, those terms are used merely as a matter of convenience in the description of one or more of the embodiments.

The term “polymer” includes homopolymers and copolymers, as well as homopolymers or copolymers that may be formed in a miscible blend, e.g., by coextrusion or by reaction, including, e.g., transesterification. Copolymers include both random and block copolymers.

The term “crosslinked” polymer refers to a polymer whose polymer chains are joined together by covalent chemical bonds, usually via crosslinking molecules or groups, to form a network polymer. A crosslinked polymer is generally characterized by insolubility, but may be swellable in the presence of an appropriate solvent.

The term “plurality” refers to more than one.

By using words of orientation such as “uppermost”, “atop”, and “overcoated” for the location of various elements in the disclosed multilayer and multilayer dielectric films, we refer to the relative position of an element relative to a horizontally disposed, upwardly facing first electrically conductive layer. It is not intended that the multilayer film or multilayer dielectric film should have any particular orientation in space during or after manufacture.

The above summary of the present disclosure is not intended to describe each disclosed embodiment or every implementation of the present disclosure. The description that follows more particularly exemplifies illustrative embodiments. It is to be understood, therefore, that the drawings and following description are for illustration purposes only and should not be read in a manner that would unduly limit the scope of this disclosure.

### BRIEF DESCRIPTION OF THE DRAWINGS

The disclosure may be more completely understood in consideration of the following detailed description of various embodiments of the disclosure in connection with the accompanying drawings, in which:

FIG. 1A is a diagram illustrating an embodiment of a multilayer film according to the present disclosure,

FIG. 1B is a diagram illustrating another embodiment of a multilayer film according to the present disclosure, and

FIG. 2 is a diagram illustrating an embodiment of a process and apparatus for making a multilayer film according to the present disclosure.

### DETAILED DESCRIPTION

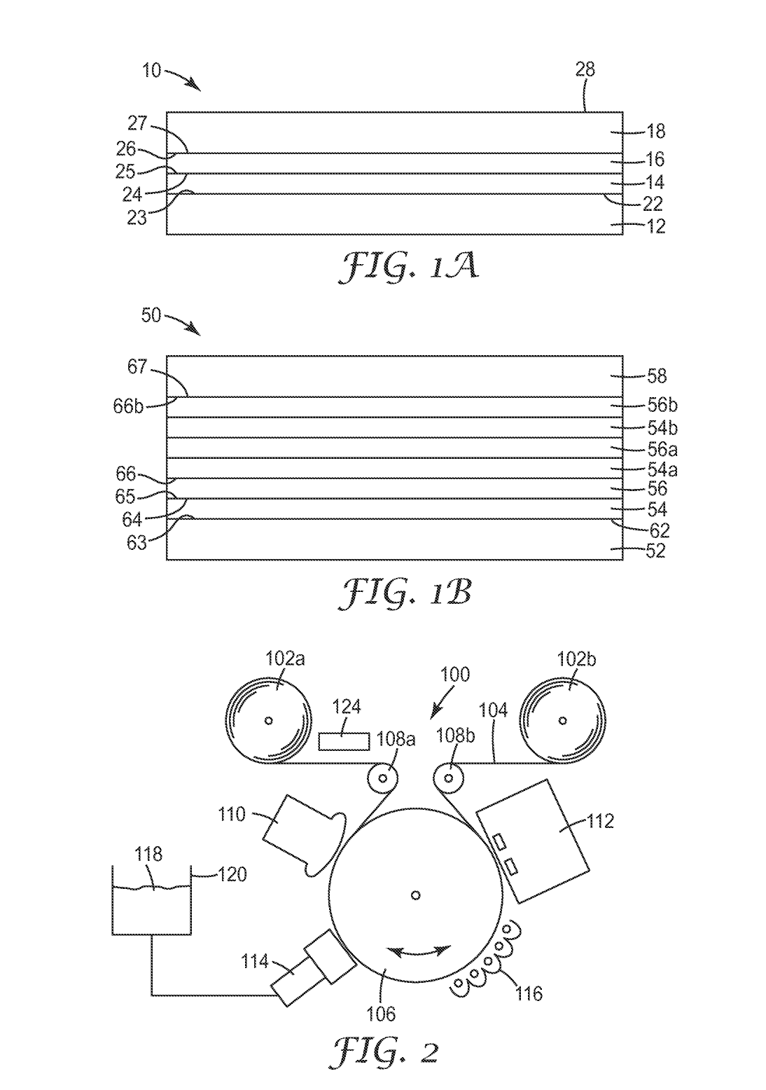

FIG. 1A is a diagram of an embodiment of a multilayer film 10 according to the present disclosure. Film 10 includes a first electrically conductive layer 12; a first dielectric layer 14 disposed on the surface of the first electrically conductive layer 12; a second dielectric layer 16 disposed on the first dielectric layer; and a second electrically conductive layer 18 disposed on the second dielectric layer. The first electrically conductive layer 12 has a first major surface 22. The first dielectric layer 14 has first and second major surfaces 23 and 24, respectively, with the first major surface 23 in contact with the first major surface 22 of the first electrically conductive layer 12. The second dielectric layer 16 has first and second major surfaces 25 and 26, respectively, with the first major surface 25 in contact with the second major surface 24 of the first dielectric layer 14. The second electrically conductive layer 18 has first and second major surfaces 27 and 28, respectively. In the illustrated embodiment, the first major surface 27 of the second electrically conductive layer 18 is in contact with the second major surface 26 of the second dielectric layer 16.

In the illustrated embodiment, the surfaces 22, 23, 24, 25, 26, and 27 appear flat, with 100% of each two neighboring surfaces in physical contact with each other. However, this is not a requirement. In some embodiments, any of the first electrically conductive layer 12, first dielectric layer 14, second dielectric layer 16, or second electrically conductive layer 18 may have surface roughness or surface features that prevent two neighboring surfaces to contact each other in certain locations. In some embodiments, substantial portions of each two neighboring major surfaces in the multilayer film (e.g., major surfaces 22 and 23, 24 and 25, or 26 and 27) are in physical contact with each other. In these embodiments, a substantial portion of a major surface can be at least 50, 60, 70, 75, 80, 85, 90, 95, 98, or 99 percent of the area of the major surface. Accordingly, in some embodiments, at least 50, 60, 70, 75, 80, 85, 90, 95, 98, or 99 percent by area of each two neighboring major surfaces in the multilayer film (e.g., major surfaces 22 and 23, 24 and 25, or 26 and 27) are in physical contact with each other.

The first electrically conductive layer conveniently serves as a substrate on which the first and second dielectric layers are built, and it also serves as an electrode in a finished capacitor, for example. The first electrically conductive layer typically comprises a metal and can include a conductive elemental metal, a conductive metal alloy, a conductive metal oxide, a conductive metal nitride, a conductive metal carbide, or a conductive metal boride. Examples of useful conductive metals include elemental silver, copper, aluminum, gold, palladium, platinum, nickel, rhodium, ruthenium, aluminum, zinc, and combinations thereof. Examples of useful conductive metal alloys include stainless steel. In some embodiments, the first electrically conductive layer is conveniently a metal foil. In some embodiments, the metal foil comprises at least one of copper or nickel. For example, the metal foil can comprise copper or its alloys, copper-invar-copper-invar, nickel, nickel-coated copper. In some embodiments, the metal foil comprises stainless steel. In some embodiments, the first electrically conductive layer is a copper foil. Copper foils are available from a variety of suppliers (e.g., Oak Mitsui, Hoosick Falls, N.Y., JX Nippon Mining & Metals, Chandler, Ark., Olin Brass Corporation, Louisville, Ky., and Carl Schlenk A G, Barnsdorf, Germany).

For any of the aforementioned embodiments of the first electrically conductive layer 12, this layer may have a thickness of at least 1 micrometer, in some embodiments, at least 5, 10, 15, or 20 micrometers. The thickness of the first electrically conductive layer may be up to 100 micrometers, in some embodiments, 75 micrometers. For example, the thickness of the first electrically conductive layer may be in a range from 1 micrometer to 100 micrometers, 5 micrometers to 100 micrometers, 10 micrometers to 100 micrometers, 20 micrometers to 100 micrometers, 1 micrometer to 75 micrometers, or 10 micrometers to 75 micrometers. A thickness of a first electrically conductive layer may be selected or designed depending, for example, on the desired flexibility of the multilayer film.

Advantageously, the multilayer films according to the present disclosure can often be prepared without cleaning or treating the first electrically conductive layer or substrate. However, in some embodiments, the first electrically conductive layer may be cleaned, for example, with solvent (e.g., isopropyl alcohol) or with an acidic etching solution (e.g., including hydrochloric acid). The first electrically conductive layer can also be cleaned with inductively coupled plasma.

Electrically conductive first layers can have a variety of surface roughness values. For example, as received from a manufacturer, a metal foil can have an average surface roughness in a range from five nanometers to 250 nanometers (nm). The average surface roughness is the arithmetic average of absolute values. The surface roughness is measured with a profilometer, for example, a Dektak 6M Stylus Profiler manufactured by Veeco Instruments, Inc., Plainview, N.Y., using an average of two or three measurements. In some embodiments, the average roughness of a surface of the first electrically conductive layer on which the first dielectric layer is disposed is at least 5 nm, 7.5 nm, or 10 nm. In some embodiments, the average roughness of a surface of the first electrically conductive layer on which the first dielectric layer is disposed is up to 250 nm, 200 nm, or 150 nm. For example, the average roughness of a surface of the first electrically conductive layer may be in a range from 5 nm to 250 nm, 5 nm to 200 nm, 5 nm to 150 nm, 5 nm to 100 nm, or 5 nm to 90 nm.

In some embodiments, the smoothness and continuity of the first dielectric layer 14 and its adhesion to the first electrically conductive layer 12 or substrate may be enhanced by appropriate pretreatment. Examples of a suitable pretreatment regimen include an electrical discharge in the presence of a suitable reactive or non-reactive atmosphere (e.g., plasma, glow discharge, corona discharge, dielectric barrier discharge or atmospheric pressure discharge); chemical pretreatment; or flame pretreatment. These pretreatments help make the surface of the first electrically conductive layer more receptive to formation of the subsequently applied first dielectric layer. In some embodiments, the first electrically conductive layer is plasma treated before the first dielectric layer is applied.

Returning to FIG. 1A, the first dielectric layer 14 is disposed on (e.g., disposed directly on) the first electrically conductive layer 12, including any of the embodiments described above for the first electrically conductive layer. The first dielectric layer 14 is typically a polymer layer, usually an organic polymer layer. The first dielectric layer can include any polymer, for example, suitable for deposition in a thin film. Typically, the polymer in the first dielectric layer is crosslinked. Since the first dielectric layer 14 is typically a polymer layer, the dielectric constant of the first dielectric layer is typically less than 20, in some embodiments, less than 15, 10, or 5, and the breakdown field strength may be in a range from 75 Volts (V)/micrometer to 150 V/micrometer, in some embodiments, 95 V/micrometer to 125 V/micrometer.

The first dielectric layer 14 can be formed on the first electrically conductive layer 12 by placing a monomer or monomer mixture onto the first electrically conductive layer 12 and then crosslinking using actinic radiation, for example. The monomer or monomer mixture can be coated using conventional coating methods such as roll coating (e.g., gravure roll coating) or spray coating (e.g., electrostatic spray coating). Chemical Vapor Deposition (CVD) may also be employed in some cases. The first dielectric layer 14 can also be formed by applying a layer containing polymer in solvent and drying to remove the solvent.

In some embodiments, the first dielectric layer 14 can be formed on the first electrically conductive layer by condensation of a vaporized liquid. For example, the first dielectric layer 14 can be formed by applying a radiation-crosslinkable monomer or monomer mixture to the first electrically conductive layer (e.g., by evaporation and vapor deposition) and crosslinking the monomer or monomer mixture to form the polymer in situ using, for example, an electron beam apparatus, UV light source, electrical discharge apparatus or other suitable device. The vaporized liquid can formed, for example, by flash evaporation or atomization of a liquid although other techniques may also be useful. Coating efficiency can be improved by cooling the substrate. The monomer or monomer mixture can include esters, vinyl compounds, alcohols, carboxylic acid anhydrides, acyl halides, thiols, amines, and mixtures thereof. In some embodiments, the first dielectric layer comprises polyvinylidene fluoride.

In some embodiments, the monomer or monomer mixtures include acrylate or methacrylate monomers and/or oligomers that include acrylates or methacrylates. Examples of useful methacrylate and acrylate precursors include urethane acrylates, isobornyl acrylate, isobornyl methacrylate, dipentaerythritol pentaacrylates, epoxy acrylates, epoxy acrylates blended with styrene, di-trimethylolpropane tetraacrylates, diethylene glycol diacrylates, 1,3-butylene glycol diacrylate, pentaacrylate esters, pentaerythritol tetraacrylates, pentaerythritol triacrylates, ethoxylated (3) trimethylolpropane triacrylates, ethoxylated (3) trimethylolpropane triacrylates, alkoxylated trifunctional acrylate esters, dipropylene glycol diacrylates, neopentyl glycol diacrylates, ethoxylated (4) bisphenol a dimethacrylates, cyclohexane dimethanol diacrylate esters, cyclic diacrylates and tris(2-hydroxy ethyl) isocyanurate triacrylate, acrylates of the foregoing methacrylates and methacrylates of the foregoing acrylates. Further examples of useful acrylate or methacrylate precursors include trimethylolpropane triacrylate, trimethylolpropane diacrylate, hexanediol diacrylate, ethoxyethyl acrylate, phenoxyethyl acrylate, cyanoethyl (mono)acrylate, octadecyl acrylate, isodecyl acrylate, lauryl acrylate, beta-carboxyethyl acrylate, tetrahydrofurfuryl acrylate, dinitrile acrylate, pentafluorophenyl acrylate, nitrophenyl acrylate, 2-phenoxyethyl acrylate, 2,2,2-trifluoromethyl acrylate, and methacrylates of any of these acrylates.

In some embodiments, the first dielectric layer 14 comprises a polymerized (e.g., crosslinked) acrylate or methacrylate. In some of these embodiments, the acrylate or methacrylate is tricyclodecanedimethanol diacrylate, 3-(acryloxy)-2-hydroxy-propylmethacrylate, triacryloxyethyl isocyanurate, glycerol diacrylate, ethoxylated trimethylolpropane diacrylate, pentaerythritol triacrylate, pentaerythritol tetraacrylate, propoxylated (3) glyceryl diacrylate, propoxylated (5,5) glyceryl diacrylate, propoxylated (3) trimethylolpropane diacrylate, propoxylated (6) trimethylolpropane diacrylate, trimethylolpropane diacrylate, trimethylolpropane triacrylate, di-trimethylolpropane tetraacrylate, dipentaerythritol pentaacrylate, or combinations thereof.

Useful methods for flash evaporation and vapor deposition followed by crosslinking in situ, can be found, for example, in U.S. Pat. No. 4,696,719 (Bischoff), U.S. Pat. No. 4,722,515 (Ham), U.S. Pat. No. 4,842,893 (Yializis et al.), U.S. Pat. No. 4,954,371 (Yializis), U.S. Pat. No. 5,018,048 (Shaw et al.), U.S. Pat. No. 5,032,461 (Shaw et al.), U.S. Pat. No. 5,097,800 (Shaw et al.), U.S. Pat. No. 5,125,138 (Shaw et al.), U.S. Pat. No. 5,440,446 (Shaw et al.), U.S. Pat. No. 5,547,908 (Furuzawa et al.), U.S. Pat. No. 6,045,864 (Lyons et al.), U.S. Pat. No. 6,231,939 (Shaw et al. and U.S. Pat. No. 6,214,422 (Yializis); in PCT International Publication No. WO 00/26973 (Delta V Technologies, Inc.); in D. G. Shaw and M. G. Langlois, “A New Vapor Deposition Process for Coating Paper and Polymer Webs”, 6th International Vacuum Coating Conference (1992); in D. G. Shaw and M. G. Langlois, “A New High Speed Process for Vapor Depositing Acrylate Thin Films: An Update”, Society of Vacuum Coaters 36th Annual Technical Conference Proceedings (1993); in D. G. Shaw and M. G. Langlois, “Use of Vapor Deposited Acrylate Coatings to Improve the Barrier Properties of Metallized Film”, Society of Vacuum Coaters 37th Annual Technical Conference Proceedings (1994); in D. G. Shaw, M. Roehrig, M. G. Langlois and C. Sheehan, “Use of Evaporated Acrylate Coatings to Smooth the Surface of Polyester and Polypropylene Film Substrates”, RadTech (1996); in J. Affinito, P. Martin, M. Gross, C. Coronado and E. Greenwell, “Vacuum deposited polymer/metal multilayer films for optical application”, Thin Solid Films 270, 43-48 (1995); and in J. D. Affinito, M. E. Gross, C. A. Coronado, G. L. Graff, E. N. Greenwell and P. M. Martin, “Polymer-Oxide Transparent Barrier Layers”, Society of Vacuum Coaters 39th Annual Technical Conference Proceedings (1996).

The monomer or monomer mixture described above in any of its embodiments may include a photoinitiator, and the monomer or monomer mixture is irradiated with ultraviolet radiation from a lamp, for example, typically in an inert atmosphere such as nitrogen, to form a polymerized and typically crosslinked first dielectric layer on the surface of the first electrically conductive layer. Examples of useful photoinitiators include benzoin ethers (e.g., benzoin methyl ether or benzoin butyl ether); acetophenone derivatives (e.g., 2,2-dimethoxy-2-phenylacetophenone or 2,2-diethoxyacetophenone); 1-hydroxycyclohexyl phenyl ketone; and acylphosphine oxide derivatives and acylphosphonate derivatives (e.g., bis(2,4,6-trimethylbenzoyl)phenylphosphine oxide, diphenyl-2,4,6-trimethylbenzoylphosphine oxide, isopropoxyphenyl-2,4,6-trimethylbenzoylphosphine oxide, or dimethyl pivaloylphosphonate). Many photoinitiators are available, for examples, from BASF, Florham Park, N.J., under the trade designation “IRGACURE”. In some cases electron-beam radiation can be used for polymerizing and crosslinking the monomer or monomer mixture to form the first dielectric layer, and a photoinitiator need not be used.

The amount of actinic radiation useful for polymerizing and crosslinking depends on a number of factors including the amount and type of reactants involved, the energy source, web speed, the distance from the energy source, and the thickness of the coating composition. Ultraviolet radiation may be useful to provide from about 0.1 to about 10 Joules per square centimeter total energy exposure, and useful amounts of electron beam radiation provide a total energy exposure in a range from less than 1 megarad to 100 megarads or more (in some embodiments, in a range from 1 to 10 megarads). Exposure times may be in a range from less than about one second up to ten minutes or more.

The desired chemical composition and thickness of the first dielectric layer will depend in part on the nature and surface topography of the first electrically conductive layer. The thickness typically is sufficient to provide some planarization of the first electrically conductive layer. Capacitance density in a capacitor, which is the measured capacitance of a capacitor divided by the common area of the electrodes in a capacitor, is inversely proportional to the dielectric thickness, and typically higher capacitance densities are desired for embedded capacitor applications. The first dielectric layer may have a thickness of several nanometers (nm) (e.g., 10 nm, 20 nm, or 30 nm) to about 1 micrometer. In some embodiments, the first dielectric layer has a thickness up to 750 nm, 600 nm, or 500 nm. In any of these embodiments, the first dielectric layer can have a thickness of at least 50 nm, 75 nm, or 100 nm. In some embodiments, the first dielectric layer has a thickness in a range from 25 nm to 900 nm, 50 nm to 750 nm, 100 nm to 600 nm, or 100 nm to 500 nm.

The first dielectric layer on an electrically conductive substrate serves as a planarizing dielectric layer that can mitigate problems with surface roughness and foreign particle contamination. For example, the surface roughness of the film after the first dielectric layer is provided on the surface of the first electrically conductive layer may decrease the surface roughness by 5%, 10%, 20%, 30%, 40%, 50%, 60%, 70%, or 75% or more in comparison to the surface roughness of the first electrically conductive layer. Typically, however, there are defects in the first dielectric layer that may be in the form of cracks or pinholes, particularly as the thickness of the first dielectric layer is minimized. In many embodiments, the second dielectric layer, when disposed directly on the first dielectric layer, can cover any cracks or pinholes that are formed in the first dielectric layer.

Referring again to FIG. 1A, the multilayer film according to the present disclosure includes a second dielectric layer 16 disposed on the first dielectric layer 14. The second dielectric layer is generally different from the first dielectric layer and has a greater dielectric constant than the first dielectric layer. In some embodiments, the second dielectric layer has a dielectric constant that is greater than 5, 10, 15, 20, 25, or 30. In some embodiments, the second dielectric layer comprises a ceramic. In these embodiments, the breakdown field strength may be in a range from 5 V/micrometer to 25 V/micrometer, in some embodiments, 10 V/micrometer to 20 V/micrometer.

The second dielectric layer may have a dielectric constant greater than 100, in some embodiments, in a range from 100 to 1000. Examples of suitable ceramics having dielectric constants greater than 100 include barium titanate (BaTiO₃), barium strontium titanate (BaSrTiO₃), lead titanate (PbTiO₃), lead zirconate titanate [Pb(ZrₓTi₁₋ₓ)O₃], lead lanthanum zirconate titanate, lead magnesium niobate (Pb(Mg_{1/3}Nb_{2/3})O₃), lead niobate (PbNb₂O₆), bismuth titanate (Bi₄Ti₃O₁₂), lead bismuth niobate (PbBi₂Nb₂O₉), strontium titanate (SrTiO₃), calcium copper titanate (CaCu₃Ti₄O₁₂), and iron titanium tantalate (FeTiTaO₆). In some embodiments, the second dielectric layer has a dielectric constant at least or greater than 10 and up to about 100. Examples of these materials suitable for multilayer film disclosed herein include transition metal oxides (e.g., Ta₂O₅, ZrO₂, HfO₂, TiO₂, and yttria-stabilized ZrO₂), hafnium silicate compounds (e.g., HfSiO and HfSiON), and CaTiO₃. In some embodiments, the second dielectric layer comprises zirconia (ZrO₂). In some embodiments, the second dielectric layer comprises yttria-stabilized zirconia.

The second dielectric layer 16 can be formed using techniques employed in the film metalizing art such as sputtering (e.g., cathode or planar magnetron sputtering), evaporation (e.g., resistive or electron beam evaporation), chemical vapor deposition, plating and the like. In some embodiments, the second dielectric layer 16 is formed by sputtering (in other words, a sputter deposition process).

A sputter deposition process can use dual targets powered by an alternating current (AC) power supply in the presence of a gaseous atmosphere having inert and/or reactive gases, for example argon and oxygen, respectively. The AC power supply alternates the polarity to each of the dual targets such that for half of the AC cycle one target is the cathode and the other target is the anode. On the next cycle the polarity switches between the dual targets. This switching typically occurs at a set frequency. Oxygen that is introduced into the process forms oxide layers on both the substrate receiving the inorganic composition and also on the surface of the target. The dielectric oxides can become charged during sputtering, thereby disrupting the sputter deposition process. Polarity switching can neutralize the surface material being sputtered from the targets, and can provide uniformity and better control of the deposited material.

The sputter deposition process can alternatively use targets powered by direct current (DC) power supplies in the presence of a gaseous atmosphere having inert and/or reactive gases, for example argon and oxygen, respectively. The DC power supplies supply power (e.g. pulsed power) to each cathode target independent of the other power supplies. In this aspect, each individual cathode target and the corresponding material can be sputtered at differing levels of power, providing additional control of composition through the layer thickness. The pulsing aspect of the DC power supplies is similar to the frequency aspect in AC sputtering, allowing control of high rate sputtering in the presence of reactive gas species such as oxygen. Pulsing DC power supplies allow control of polarity switching, can neutralize the surface material being sputtered from the targets, and can provide uniformity and better control of the deposited material.

In some embodiments, the sputter deposition process is carried out by radio frequency sputtering. In radio frequency (RF) sputtering, targets are powered by RF power supplies in the presence of a gaseous atmosphere having inert gases or a combination of inert and reactive gases, for example argon and oxygen, respectively. Charge build-up on insulating targets can be avoided in RF sputtering. A variety of gas pressures may be useful, for example in a range from 0.133 Pa to 2 Pa. In some embodiments, an argon pressure of at least 1.2 Pa is useful.

The second dielectric layer may have a variety of useful thicknesses. For example, the second dielectric layer may have a thickness of several nm (e.g., 10 nm, 20 nm, or 30 nm) to about 2 micrometers. In some embodiments, the second dielectric layer has a thickness up to 1 micrometer, 750 nanometers, or 500 nanometers. In any of these embodiments, the second dielectric layer can have a thickness of at least 100, 150, 200, 250, or 300 nm. In some embodiments, the second dielectric layer has a thickness in a range from 100 nm to 900 nm, 150 nm to 750 nm, 300 nm to 750 nm, or 300 nm to 600 nm. As described above for the first dielectric layer, capacitance density is inversely proportional to the dielectric thickness, and typically higher capacitance densities are desired for embedded capacitor applications.

Referring again to FIG. 1A, the multilayer film according to the present disclosure includes a second electrically conductive layer 18 disposed on the second dielectric layer 16. The second electrically conductive layer can serve as an electrode in a finished capacitor, for example. The second electrically conductive layer can include a conductive elemental metal, a conductive metal alloy, a conductive metal oxide, a conductive metal nitride, a conductive metal carbide, or a conductive metal boride. Examples of useful conductive metals for the second electrically conductive layer include elemental silver, copper, aluminum, gold, palladium, platinum, nickel, rhodium, ruthenium, aluminum, zinc, and combinations thereof. The second electrically conductive layer can be formed by a variety of methods. For example, sputtering (e.g., using any of the techniques described above), evaporation, combustion chemical vapor deposition, electroless plating, and printing may be useful. It may be useful to form a seed layer of a conductive metal by sputtering, for example, followed by electroplating to increase the thickness of the second electrically conductive layer. In some embodiments, the second electrically conductive layer is continuous for at least a major portion of the multilayer film. In other embodiments, the second electrically conductive layer can be placed in discrete areas over the second dielectric layer. For example, a shadow mask may be used during sputtering to provide several electrodes on the surface of the second dielectric layer.

For any of the aforementioned embodiments of the second electrically conductive layer, the second electrically conductive layer may have a thickness of at least 1 micrometer, in some embodiments, at least 5, 10, 15, or 20 micrometers. The thickness of the second electrically conductive layer may be up to 100 micrometers, in some embodiments, 75 micrometers. For example, the thickness of the second electrically conductive layer may be in a range from 1 micrometer to 100 micrometers, 5 micrometers to 100 micrometers, 10 micrometers to 100 micrometers, 20 micrometers to 100 micrometers, 1 micrometer to 75 micrometers, or 10 micrometers to 75 micrometers.

In some embodiments, including any of the aforementioned embodiments, second electrically conductive layer 18 may be formed directly on second dielectric layer 16. In other embodiments, including any of the aforementioned embodiments, an adhesion-promoting layer (tie layer) may be present between the second dielectric layer 16 and the second electrically conductive layer 18. Examples of suitable adhesion promoting layers include a layer of a metal, an alloy, an oxide, a metal oxide, a metal nitride, and a metal oxynitride. In some embodiments, the adhesion-promoting layer comprises chromium, titanium, nickel, nickel-chromium alloys, or indium tin oxide. The adhesion-promoting layer may have a thickness from a few nanometers (e.g., 1 or 2 nanometers) to about 10 nanometers, for example, and can be thicker if desired. The adhesion-promoting layer can be formed by sputtering (e.g., including any of the techniques described above), evaporation (e.g., resistive or electron beam evaporation), or chemical vapor deposition, for example.

FIG. 1B is a diagram of another embodiment of a multilayer film according to the present disclosure. Film 50 includes first and second electrically conductive layers 52 and 58 separated by at least a first dielectric layer 54 and a second dielectric layer 56. In the embodiment illustrated in FIG. 1B, the multilayer film includes a plurality of alternating layers of first dielectric layer 54 and second dielectric layer 56. First dielectric layer 54 is disposed on the surface of the first electrically conductive layer 52, and second dielectric layer 56 is disposed on the first dielectric layer 54. The first electrically conductive layer 52 has a first major surface 62. The first dielectric layer 54 has first and second major surfaces 63 and 64, respectively, with the first major surface 63 in contact with the first major surface 62 of the first electrically conductive layer 52. The second dielectric layer 56 has first and second major surfaces 65 and 66, respectively, with the first major surface 65 in contact with the second major surface 64 of the first dielectric layer 54. The first and second dielectric layers are repeated in alternating layers, with a repeat of first dielectric layer 54a disposed on the second major surface 66 of second dielectric layer 66, a repeat of the second dielectric layer 56a disposed on the first dielectric layer 54a, and an additional pair of first and second layers 54b and 56b. The second electrically conductive layer 58 is overcoated on the alternating first and second dielectric layers and has first major surface 67 in contact with the second major surface 66b of second dielectric layer 56b.

In the embodiment illustrated in FIG. 1B, any of the materials and methods useful for providing the first electrically conduction layer, first dielectric layer, second dielectric layer, and second electrically conductive layer described above in any of their embodiments (e.g., in connection with FIG. 1A and including any surface cleaning, pretreatments, or tie layers) may be useful. In some of these embodiments, each first dielectric layer may have a thickness of several nm (e.g., 10 nm or 15 nm) to about 100 nanometers. For example, the first dielectric layer can have a thickness in a range from 10 nm to 100 nm, 10 nm to 75 nm, 10 nm to 50 nm, 15 nm to 100 nm, 15 nm to 75 nm, or 15 nm to 50 nm. Furthermore, for some of the embodiments including multiple, alternating first and second dielectric layers, each second dielectric layer may have a thickness of several nm (e.g., 10 nm or 15 nm) to about 100 nanometers. For example, the second dielectric layer can have a thickness in a range from 10 nm to 100 nm, 10 nm to 75 nm, 10 nm to 50 nm, 15 nm to 100 nm, 15 nm to 75 nm, or 15 nm to 50 nm.

For embedded capacitor applications, the combination of first and second dielectric layers of the multilayer dielectric film disclosed herein typically provides a high yield of functional capacitors on flexible substrates with acceptable capacitance density values. As described above, the first dielectric layer can mitigate problems with the surface of the first electrically conductive layer. Furthermore, although the breakdown filed strength of the material in the second dielectric layer is typically lower than the breakdown field strength of the material in the first dielectric layer, the presence of the second dielectric layer can increase the breakdown field strength of a localized point in the dielectric material because it can serve to heal defects in the first dielectric layer. Together, the first and second dielectric layer can provide a higher yield of functional capacitors than a dielectric layer of comparable thickness but having only one of the first or second dielectric layers. This advantage is demonstrated in the Examples, below. In Example 1, a multilayer film according to the present disclosure was prepared. In this example film, the first and second dielectric layers had a combined thickness of 800 nm. A 100% yield was observed for 5-mm-diameter functional capacitors prepared from the multilayer film disclosed herein. In contrast, 75% yield was observed for 5-mm-diameter functional capacitors having same construction except not including the second dielectric layer and having a first dielectric layer with a thickness of 900 nm. Also, functional capacitors having the same construction except not including the first dielectric layer were prepared and found to be mostly shorted.

The multilayer film according to the present disclosure can be made, for example, in whole or in part using roll-to-roll fabrication techniques although any of the methods described above can be performed in a stationary process as well. An example of an apparatus 100 that can conveniently be used to make the multilayer film according to the present disclosure is shown in FIG. 2. Powered reels 102a and 102b move substrate 104 back and forth through apparatus 100. The substrate can be first electrically conductive layer 12 as described above in any of its embodiments, for example, a metal foil. Temperature-controlled rotating drum 106 and idlers 108a and 108b carry substrate 104 past plasma source 110, monomer evaporator 114, crosslinking unit 116, and sputtering applicators 112. Monomer or a monomer mixture 118 is supplied to evaporator 114 from reservoir 120. Optionally, gas flows (e.g., nitrogen, argon, helium) can be introduced into the evaporator (not shown in FIG. 2). Vapor from the evaporator 114 passes through a nozzle or diffuser (not shown in FIG. 2) and condenses on substrate 104. Crosslinking unit 116, which can include UV lamps, can be used to produce a crosslinked polymer layer from the monomer to form the first dielectric layer. Sputtering applicators 112 can apply the second dielectric layer as the drum 106 advances the film. Infrared lamp 124 can be used to heat the substrate before or after application of one or more of the layers. Successive layers can be applied to the substrate 104 using multiple passes (in either direction) through apparatus 100. Apparatus 100 can be enclosed in a suitable chamber (not shown in FIG. 2) and maintained under vacuum or supplied with a suitable inert atmosphere in order to discourage oxygen, dust and other atmospheric contaminants from interfering with the various pretreatment, evaporation, condensation, crosslinking, and sputtering steps.

Other roll-to-roll vacuum chamber fabrication apparatuses that may be useful for preparing a multilayer film according to the present disclosure are described in U.S. Pat. No. 5,440,446 (Shaw et al.) and U.S. Pat. No. 7,018,713 (Padiyath, et al.).

In a roll-to-roll process, the thickness of the first dielectric layer can be adjusted based on the formula [t=q/(s*w)], where t=thickness, q=monomer flow rate, s=coating drum speed and w=monomer deposition source width. The exposure time to actinic radiation (e.g., UV light) can be adjusted based on the thickness of the first dielectric layer, with longer residence times being useful for thicker layers.

Unlike films for certain optical applications, multilayer films according to the present disclosure need not always be transmissive to visible and optionally other wavelengths of light. In some embodiments of the multilayer films disclosed herein, the multilayer film has an average visible light transmission of up to about 10 percent (in some embodiments, up to about 9, 8, 7, 6, 5, 4, 3, 2, or 1 percent). In some embodiments, the multilayer film has an average transmission over a range of 390 nm to 750 nm of up to about 10 percent (in some embodiments, up to about 9, 8, 7, 6, 5, 4, 3, 2, or 1 percent). In some embodiments of the multilayer films disclosed herein, at least one of the first or the second electrically conductive layer has an average visible light transmission of up to about 10 percent (in some embodiments, up to about 9, 8, 7, 6, 5, 4, 3, 2, or 1 percent). In some embodiments, at least one of the first or the second electrically conductive layer has an average transmission over a range of 390 nm to 750 nm of up to about 10 percent (in some embodiments, up to about 9, 8, 7, 6, 5, 4, 3, 2, or 1 percent).

In some embodiments, multilayer films according to the present disclosure are flexible. The term “flexible” as used herein refers to being capable of being formed into a roll. In some embodiments, the term “flexible” refers to being capable of being bent around a roll core with a radius of curvature of up to 7.6 centimeters (cm) (3 inches), in some embodiments up to 6.4 cm (2.5 inches), 5 cm (2 inches), 3.8 cm (1.5 inch), or 2.5 cm (1 inch). In some embodiments, the multilayer film can be bent around a radius of curvature of at least 0.635 cm (¼ inch), 1.3 cm (½ inch) or 1.9 cm (¾ inch).

### Some Embodiments of the Disclosure

In a first embodiment, the present disclosure provides a multilayer film, comprising:

first and second electrically conductive layers separated by at least first and second dielectric layers, with the first and second electrically conductive layers each having an average visible light transmission of less than about ten percent;

wherein the first dielectric layer is disposed on (e.g., formed directly on) the first electrically conductive layer by a condensation of a vaporized liquid; and

wherein the second dielectric layer disposed on (e.g., formed directly on) the first dielectric layer, the second dielectric layer not being formed by a condensation of a vaporized liquid.

In a second embodiment, the present disclosure provides the multilayer film of the first embodiment, wherein the vaporized liquid is formed by atomization of a liquid.

In a third embodiment, the present disclosure provides the multilayer film of the first embodiment, wherein the vaporized liquid is formed by flash evaporation of a liquid.

In an fourth embodiment, the present disclosure provides the multilayer film of any one of the first to third embodiments, wherein an average roughness of a surface of the first electrically conductive layer on which the first dielectric layer is formed is at least 10 nanometers.

In a fifth embodiment, the present disclosure provides a multilayer film, comprising:

first and second electrically conductive layers separated by first and second dielectric layers, the first electrically conductive layer having a top surface, an average roughness of the top surface being at least 10 nanometers;

wherein the first dielectric layer is disposed on (e.g., formed directly on) the top surface of the first electrically conductive layer and has a first dielectric constant; and

wherein the second dielectric layer is disposed on (e.g., formed directly on) the first dielectric layer and has a second dielectric constant greater than the first dielectric constant.

In a sixth embodiment, the present disclosure provides the multilayer film of the fifth embodiment, wherein the first dielectric layer is formed by a condensation of a vaporized liquid.

In a seventh embodiment, the present disclosure provides the multilayer film of the sixth embodiment, wherein the vaporized liquid is formed by atomization of a liquid.

In an eighth embodiment, the present disclosure provides the multilayer film of the sixth embodiment, wherein the vaporized liquid is formed by flash evaporation of a liquid.

In a ninth embodiment, the present disclosure provides the multilayer film of any one of the first to eighth embodiments, wherein the first dielectric layer has a dielectric constant less than 20.

In a tenth embodiment, the present disclosure provides the multilayer film of the ninth embodiment, wherein the first dielectric layer has a dielectric constant less than 10.

In an eleventh embodiment, the present disclosure provides the multilayer film of any one of the first to tenth embodiments, wherein the second dielectric layer has a dielectric constant greater than 20.

In a twelfth embodiment, the present disclosure provides the multilayer film of the eleventh embodiment, wherein the second dielectric layer has a dielectric constant greater than 30.

In a thirteenth embodiment, the present disclosure provides the multilayer film of any one of the first to twelfth embodiments, wherein the first and second electrically conductive layers comprise metal.

In a fourteenth embodiment, the present disclosure provides the multilayer film of any one of the first to thirteenth embodiments, wherein the first electrically conductive layers comprises a metal foil.

In a fifteenth embodiment, the present disclosure provides a multilayer film, comprising:

a first metal layer having a surface, an average roughness of the surface being at least ten nanometers;

a first dielectric layer disposed on (e.g., formed directly on) the surface of the first metal layer and having a first dielectric constant less than 20;

a second dielectric layer disposed on (e.g., formed directly on) the first dielectric layer and having a second dielectric constant greater than 20; and

a second metal layer electroplated atop at least the first metal layer, the first dielectric layer, and the second dielectric layer.

In a sixteenth embodiment, the present disclosure provides the multilayer film of the fifteenth embodiment, wherein the first dielectric layer is formed by a condensation of a vaporized liquid.

In a seventeenth embodiment, the present disclosure provides the multilayer film of the sixteenth embodiment, wherein the vaporized liquid is formed by atomization of a liquid.

In an eighteenth embodiment, the present disclosure provides the multilayer film of the sixteenth embodiment, wherein the vaporized liquid is formed by flash evaporation of a liquid.

In a nineteenth embodiment, the present disclosure provides the multilayer film of any one of the fifteenth to the eighteenth embodiments, wherein the first dielectric layer has a dielectric constant less than 10.

In a twentieth embodiment, the present disclosure provides the multilayer film of any one of the fifteenth to the nineteenth embodiments, wherein the second dielectric layer has a dielectric constant greater than 30.

In a twenty-first embodiment, the present disclosure provides the multilayer film of any one of the first to twentieth embodiments, wherein a thickness of the first dielectric layer is less than one micrometer.

In twenty-second embodiment, the present disclosure provides the multilayer film of any one of the first to twenty-first embodiments, wherein a thickness of the second dielectric layer is less than one micrometer.

In a twenty-third embodiment, the present disclosure provides the multilayer film of any one of the first to twenty-second embodiments, wherein the first dielectric layer comprises a polymer.

In a twenty-fourth embodiment, the present disclosure provides the multilayer film of any one of the first to twenty-third embodiments, wherein the second dielectric layer is formed by sputtering.

In a twenty-fifth embodiment, the present disclosure provides the multilayer film of any one of the first to twenty-fourth embodiments, wherein the second dielectric layer comprises zirconia.

In a twenty-sixth embodiment, the present disclosure provides the multilayer film of the twenty-fifth embodiment, wherein the second dielectric layer comprises yttria-stabilized zirconia.

In a twenty-seventh embodiment, the present disclosure provides the multilayer film of any one of the first to twenty-sixth embodiments, wherein a thickness of the first electrically conductive layer is greater than ten micrometers.

In a twenty-eighth embodiment, the present disclosure provides the multilayer film of the twenty-seventh embodiment, wherein a thickness of the first electrically conductive layer is greater than 20 micrometers.

In a twenty-ninth embodiment, the present disclosure provides the multilayer film of any one of the first to twenty-eighth embodiments, wherein a thickness of the second electrically conductive layer is greater than ten micrometers.

In a thirtieth embodiment, the present disclosure provides the multilayer film of the twenty-ninth embodiment, wherein a thickness of the second electrically conductive layer is greater than 20 micrometers.

In a thirty-first embodiment, the present disclosure provides a multilayer film, comprising:

a first electrically conductive layer having a thickness greater than ten micrometers;

a first dielectric layer disposed on (e.g., formed directly on) the surface of the first electrically conductive layer and having a thickness less than one micrometer, the first dielectric layer being a polymer layer;

a second dielectric layer disposed on (e.g., formed directly on) the first dielectric layer and having a thickness less than one micrometer, the second dielectric layer being a ceramic layer; and

a second electrically conductive layer having a thickness greater than ten micrometers atop at least the first electrically conductive layer and the first and second dielectric layer.

In a thirty-second embodiment, the present disclosure provides a multilayer film, comprising:

first and second electrically conductive layers separated by at least first and second dielectric layers, wherein the first electrically conductive layer has at least one of an average surface roughness of at least ten nanometers or a thickness of at least ten micrometers;

wherein the first dielectric layer comprises a polymer and is disposed on (e.g., disposed directly on) the surface of the first electrically conductive layer;

wherein the second dielectric layer comprises a ceramic and is disposed on (e.g., disposed directly on) the first dielectric layer.

In a thirty-third embodiment, the present disclosure provides the multilayer film of the thirty-second embodiment, wherein a thickness of the first dielectric layer is less than one micrometer.

In thirty-fourth embodiment, the present disclosure provides the multilayer film of the thirty-second or thirty-third embodiments, wherein a thickness of the second dielectric layer is less than one micrometer.

In a thirty-fifth embodiment, the present disclosure provides the multilayer film of any one of the thirty-second to thirty-fourth embodiments, wherein a thickness of the first electrically conductive layer is greater than ten micrometers.

In a thirty-sixth embodiment, the present disclosure provides the multilayer film of any one of the thirty-second to thirty-fifth embodiments, wherein a thickness of the second electrically conductive layer is greater than ten micrometers.

In a thirty-seventh embodiment, the present disclosure provides the multilayer film of any one of the thirty-first to thirty-sixth embodiments, wherein the first and second electrically conductive layers comprise metal.

In a thirty-eighth embodiment, the present disclosure provides the multilayer film of any one of the thirty-first to thirty-seventh embodiments, wherein the first electrically conductive layers comprises a metal foil.

In a thirty-ninth embodiment, the present disclosure provides the multilayer film of any one of the thirty-first to thirty-eighth embodiments, wherein the first dielectric layer is formed by a condensation of a vaporized liquid.

In a fortieth embodiment, the present disclosure provides the multilayer film of the thirty-ninth embodiment, wherein the vaporized liquid is formed by atomization of a liquid.

In forty-first embodiment, the present disclosure provides the multilayer film of the thirty-ninth embodiment, wherein the vaporized liquid is formed by flash evaporation of a liquid.

In a forty-second embodiment, the present disclosure provides the multilayer film of any one of the thirty-first to the forty-first embodiments, wherein the first dielectric layer has a dielectric constant less than 20.

In a forty-third embodiment, the present disclosure provides the multilayer film of the forty-second embodiment, wherein the first dielectric layer has a dielectric constant less than 10.

In a forty-forth embodiment, the present disclosure provides the multilayer film of any one of the thirty-first to forty-third embodiments, wherein the second dielectric layer has a dielectric constant greater than 20.

In a forty-fifth embodiment, the present disclosure provides the multilayer film of any one of the thirty-first to forty-fourth embodiments, wherein the second dielectric layer has a dielectric constant greater than 30.

In a forty-sixth embodiment, the present disclosure provides the multilayer film of any one of the thirty-first to forty-fifth embodiments, wherein the second dielectric layer is formed by sputtering.

In a forty-seventh embodiment, the present disclosure provides the multilayer film of any one of the thirty-first to forty-sixth embodiments, wherein the second dielectric layer comprises zirconia.

In a forty-eighth embodiment, the present disclosure provides the multilayer film of the forty-seventh embodiment, wherein the second dielectric layer comprises yttria-stabilized zirconia.

In a forty-ninth embodiment, the present disclosure provides the multilayer film of any one of the thirty-first to forty-eighth embodiments, wherein a thickness of the first electrically conductive layer is greater than 20 micrometers.

In a fiftieth embodiment, the present disclosure provides the multilayer film of any one of the thirty-first to forty-ninth embodiments, wherein a thickness of the second electrically conductive layer is greater than 20 micrometers.

In a fifty-first embodiment, the present disclosure provides the multilayer film of any one of the thirty-first to fiftieth embodiments, wherein an average roughness of a surface of the first electrically conductive layer on which the first dielectric layer is formed is at least 10 nanometers.

In a fifty-second embodiment, the present disclosure provides the multilayer film of any one of the first to fifty-first embodiments, wherein substantial portions of each two neighboring major surfaces in the multilayer film are in physical contact with each other.

In a fifty-third embodiment, the present disclosure provides the multilayer film of any one of the first to fifty-second embodiments, wherein at least 60% of each two neighboring major surfaces in the multilayer film are in physical contact with each other.

In a fifty-fourth embodiment, the present disclosure provides the multilayer film of any one of the first to fifty-third embodiments, the multilayer film being flexible.

In a fifty-fifth embodiment, the present disclosure provides the multilayer film of any one of the first to fifty-fourth embodiments, wherein the first dielectric layer comprises polyvinylidene fluoride.

In a fifty-sixth embodiment, the present disclosure provides the multilayer film of any one of the first to fifty-fifth embodiments, comprising a plurality of alternating first and second dielectric layers.

In a fifty-seventh embodiment, the present disclosure provides use of the multilayer film of any one of the first to fifty-sixth embodiments as a capacitor.

In a fifty-eighth embodiment, the present disclosure provides a multilayer dielectric film, comprising:

a first dielectric layer comprising a first material having a first breakdown field strength; a second dielectric layer disposed on (e.g., formed directly on) the first dielectric layer and comprising a second material having a second breakdown field strength less than the first breakdown field strength, wherein the first dielectric layer has a third breakdown field strength at a localized position that is less than the second breakdown field strength, and

wherein the multilayer dielectric film has a fourth breakdown field strength at the localized position that is greater than the third breakdown field strength.

In a fifty-ninth embodiment, the present disclosure provides the multilayer dielectric film of the fifty-eighth embodiment, wherein the first dielectric layer is formed by a condensation of a vaporized liquid.

In a sixtieth embodiment, the present disclosure provides the multilayer dielectric film of the fifty-ninth embodiment, wherein the vaporized liquid is formed by atomization of a liquid.

In a sixty-first embodiment, the present disclosure provides the multilayer dielectric film of the fifty-ninth embodiment, wherein the vaporized liquid is formed by flash evaporation of a liquid.

In a sixty-second embodiment, the present disclosure provides the multilayer dielectric film of any one of the fifty-eighth to the sixty-first embodiments, wherein the second dielectric layer is not formed by a formed by a condensation of a vaporized liquid.

In a sixty-third embodiment, the present disclosure provides the multilayer dielectric film of any one of the fifty-eighth to the sixty-second embodiments, wherein the second dielectric layer is formed by sputtering.

In a sixty-fourth embodiment, the present disclosure provides the multilayer dielectric film of any one of the fifty-eighth to the sixty-third embodiments, wherein the first dielectric layer comprises a polymer.

In a sixty-fifth embodiment, the present disclosure provides the multilayer dielectric film of any one of the fifty-eighth to the sixty-fourth embodiments, wherein the second dielectric layer comprises zirconia.

In a sixty-sixth embodiment, the present disclosure provides the multilayer dielectric film of the sixty-fifth embodiment, wherein the second dielectric layer comprises yttria-stabilized zirconia.

In a sixty-seventh embodiment, the present disclosure provides the multilayer dielectric film of any one of the fifty-eighth to the sixty-sixth embodiments, wherein the first dielectric layer has a dielectric constant less than 20.

In a sixty-eighth embodiment, the present disclosure provides the multilayer dielectric film of any one of the fifty-eighth to the sixty-seventh embodiments, wherein the first dielectric layer has a dielectric constant less than 10.

In a sixty-ninth embodiment, the present disclosure provides the multilayer dielectric film of any one of the fifty-eighth to the sixty-eighth embodiments, wherein the second dielectric layer has a dielectric constant of at least 20.

In a seventieth embodiment, the present disclosure provides the multilayer dielectric film of any one of the fifty-eighth to the sixty-ninth embodiments, wherein the second dielectric layer has a dielectric constant of at least 30.

In a seventy-first embodiment, the present disclosure provides the multilayer dielectric film of any one of the fifty-eighth to the seventieth embodiments, wherein a thickness of the first dielectric layer is up to one micrometer.

In a seventy-second embodiment, the present disclosure provides the multilayer dielectric film of any one of the fifty-eighth to the seventy-first embodiments, wherein a thickness of the second dielectric layer is up to one micrometer.

In a seventy-third embodiment, the present disclosure provides the multilayer dielectric film of any one of the fifty-eighth to the seventy-second embodiments, wherein substantial portions of the first and second dielectric layers' neighboring major surfaces in the multilayer dielectric film are in physical contact with each other.

In a seventy-fourth embodiment, the present disclosure provides the multilayer dielectric film of any one of the fifty-eighth to the seventy-third embodiments, wherein at least 60 percent of the first and second dielectric layers' neighboring major surfaces in the multilayer dielectric film are in physical contact with each other.

In a seventy-fifth embodiment, the present disclosure provides the multilayer dielectric film of any one of the fifty-eighth to the seventy-fourth embodiments, the multilayer dielectric film being flexible.

In a seventy-sixth embodiment, the present disclosure provides the multilayer dielectric film of any one of the fifty-eighth to the seventy-fifth embodiments, wherein the first dielectric layer comprises polyvinylidene fluoride.

In a seventy-seventh embodiment, the present disclosure provides the multilayer dielectric film of any one of the fifty-eighth to the seventy-sixth embodiments, comprising a plurality of alternating first and second dielectric layers.

In order that this disclosure can be more fully understood, the following examples are set forth. It should be understood that these examples are for illustrative purposes only, and are not to be construed as limiting this disclosure in any manner. All parts and percentages are by weight unless otherwise indicated.

### EXAMPLES

### Example 1

Copper foil (35 micrometers thick, 6.5 inches (16.5 cm) wide) was obtained from Carl Schlenck A G, Barnsdorf, Germany, under the trade designation “ETP CDM 110”. The surface roughness of the copper foil was measured using Dektak 6M Stylus Profiler obtained from Veeco Instruments, Inc., Plainview, N.Y. Taking an average of three scans, the arithmetic average of the absolute values of the surface measurements was 11 nanometers (nm), the root mean squared was 14, the maximum valley depth was 46 nm, the maximum peak height was 64 nm, and the maximum height of the profile was 97 nm.

Multiple samples of the copper foil were taped to onto a polymer carrier film attached to the process drum 106 of the apparatus 100 generally depicted in FIG. 2. The exposed surface of the copper foil was first plasma treated using an Argon flow rate of 500 standard cubic centimeters per minute (sccm) and an Argon pressure of 300 mtorr (40 Pa). A plasma power of 600 W was used at 400 kHz, and the line speed was 30 feet per minute (9.1 meters per minute).

Then the coating drum 106 was cooled to 5° F. (−15° C.), and the plasma-treated surface was treated with a monomer mixture prepared by combining tricyclodecane dimethanol diacrylate (obtained under the trade designation “SR-833S”, from Sartomer USA, Exton, Pa.) at 0.9 mole fraction, 2-hydroxy-2-methyl-1-phenyl-1-propanone photoinitiator (obtained under the trade designation “DAROCUR 1173” from BASF, Florham Park, N.J.) at 0.04 mole fraction, and an acidic acrylate oligomer (obtained under the trade designation “CN 147”, from Sartomer USA) at 0.06 mole fraction. The monomer mixture had been vacuum degassed for twenty minutes. The degassed monomer mixture 118 was then transferred to a syringe 120, installed into a syringe pump and connected by capillary line to an atomization device. The atomization device was located at the entrance to an evaporation chamber 114 heated at 275° C.

An acrylate layer thickness of 300 nm was targeted. The liquid monomer was pumped at 0.75 mL per minute into the atomization device. Atomized droplets of monomer vapor exited the atomizer tip and flash evaporated in the heated evaporation chamber. With stabilization to steady state requiring a few minutes time, the coating drum 106 rotation was held low, then the speed was adjusted as needed for achieving the thickness target. Assuming an 83% efficiency, the formula [t=q/(s*w)], where t=coating thickness, q=monomer flow rate, s=coating drum speed and w=monomer deposition source width, was used to select the drum speed. The monomer deposition source width was 12 inches (30.5 cm), and the drum speed was about 22.3 feet per minute (6.80 meters per minute).

The monomer vapor exited the 0.030 inch (0.076 cm) coating die (slot) adjacent to the cooled coating drum and was allowed to condense upon the moving substrate. The condensed vapor was then exposed to UV lamps 116 for a residence time of 0.9 seconds and formed a solid film. The syringe pump was stopped, and the capillary valve was closed. The vacuum chamber was evacuated, and the evaporation chamber was cooled to room temperature. Samples were then removed from the drum.

Spectral reflectance scans of representative samples were used to calculate, from the reflected optical interference extrema, both coated layer thickness and refractive index. The thickness of the first dielectric layer was found to be about 300 nm.

A second dielectric layer was deposited on the first electric layer via RF sputtering using the following method. A sample of the acrylate-coated copper foil was attached to a thin ( 1/16-in. (1.6-mm) thick) aluminum plate via double-sided pressure sensitive adhesive tape. The sample was then placed acrylate coating side-down onto a carrier plate in a sputtering system load lock. The sputtering system having the model number ISE-OE-PVD-3000 was obtained from Innovative Systems Engineering, Warminster, Pa., but is no longer available. The load lock was then pumped down to a pressure of 4×10⁻⁵ Torr (0.005 Pa), at which point the sample was transferred into the main sputtering chamber. An 8% yttria in zirconia (YSZ) target (obtained from Kurt J. Lesker, Clairton, Pa.) was used. The YSZ target was 0.25 inch (0.64 cm) thick and had a diameter of 6 inches (15 cm). The target to substrate distance was roughly 5 inches (12.7 cm). The main sputtering chamber was backfilled to a pressure of 10 mTorr (1.33 Pa) of argon gas, supplied via a gas distribution ring around the YSZ cathode assembly. Lower pressures than this were found to result in significant film cracking. After a short power ramp up and 5-minute/400 W pre-sputter with the deposition shutter in the closed position, the shutter then opened for a deposition time of 36 minutes at a sputtering power of 400 W. The temperature of the aluminum plate was about 40° C. after deposition of the YSZ, showing that there was good thermal contact between the sample and the aluminum plate. After the deposition was completed, the RF power was shut off and the shutter was closed. The sample was then transferred back into the load lock. The YSZ film thickness was measured on a glass slide coated under the same conditions and found to be about 500 nm.

Gold and silver top electrodes having a thickness of 60 to 100 nm were deposited using a shadow mask in a sputtering system on the samples having the first and second dielectric layers on copper foil to provide the second electrically conductive layer. The area of the samples was about 5 cm×5 cm, and the electrodes were 5, 2, and 1 mm in diameter respectively. There were approximately 100 electrodes per sample. A LCR meter obtained from Agilent, Santa Clara, Calif., under the trade designation “E 4980 A” LCR equipped with a power supply obtained from Keithley Instruments, Inc., Cleveland, Ohio, with model number 2400 was used to evaluate the samples at a frequency of 1 kHz for capacitance and loss tangent values. The measurements were carried out using a step voltage ramp, where the current was measured at the end of each voltage step. All the measurements were done at room temperature. Capacitance (C/A ratios) in a range of 70 to 80 nF/in² (10.9 to 12.5 nF/cm²). Dielectric loss tangent (where tan δ=0.02-0.03), and Ohmic resistance values in a range from 2 to 4 megaohms were observed for the samples. 100% yield (16/16) of functional capacitors having 5-mm electrodes was observed for the test samples. Because of the larger area of the 5-mm electrodes, these are the most likely to fail, for example, by shorting.

### Example 2

For certain samples prepared in Example 1, after the first and second dielectric layers were formed, a chromium tie layer having a thickness of about 5 nm and a seed layer of copper having a thickness of about 15 nm were sequentially sputtered using DC sputtering. This structure was electroplated with copper to a thickness of about 12 micrometers.

### Illustrative Examples

Samples of copper foil (35 micrometers thick, 6.5 inches (16.5 cm) wide), obtained from Carl Schlenck A G, under the trade designation “ETP CDM 110” were plasma treated and coated with a first dielectric layer as described in Example 1. Thicknesses of the first dielectric layer of 900 nm and 600 nm were targeted to provide a dielectric layer with a thickness comparable to the 800-nm thickness of the dielectric layers of Example 1. To achieve a thickness of 600 nm, a drum speed of about 11.15 feet per minute (3.4 meters per minute) and a UV exposure time of about 1.8 seconds were used. To achieve a thickness of 900 nm, a drum speed of about 7.43 feet per minute (2.3 meters per minute) and a UV exposure time of about 2.7 seconds were used. Gold and silver top electrodes having a thickness of 60 to 100 nm were deposited using a shadow mask in a sputtering system on the samples having the first and second dielectric layers on copper foil to provide the second electrically conductive layer. The area of the samples was about 5 cm×5 cm, and the electrodes were 5, 2, and 1 mm in diameter respectively. There were approximately 100 electrodes per sample. Capacitance and loss tangent were measured for each sample using the method of Example 1. C/A ratios of 20 and 40 nF/in² (3.1 and 6.3 nF/cm², respectively,) were measured for samples having first dielectric layers that were 900 and 600 nm in thickness, respectively. Dielectric loss tangent where tan δ=0.003 and 0.005 were measured for samples having first dielectric layers that were 900 and 600 nm in thickness, respectively. 75% yield of functional capacitors having 5-mm electrodes was observed for the test samples having a 900-nm thick first dielectric layer. Lower yields of about 12% were observed when a 600-nm thick first dielectric layer was used to make capacitors with 5-mm electrodes. When capacitors were made using only a second dielectric layer using the method described in Example 1 (that is, having only a YSZ layer and no first dielectric layer) most of the capacitors were shorted.

This disclosure may take on various modifications and alterations without departing from its spirit and scope. Accordingly, this disclosure is not limited to the above-described embodiments but is to be controlled by the limitations set forth in the following claims and any equivalents thereof. This disclosure may be suitably practiced in the absence of any element not specifically disclosed herein.

1. A multilayer film, comprising:
first and second electrically conductive layers separated by at least first and second dielectric layers, with the first and second electrically conductive layers each having an average visible light transmission of less than about ten percent;
wherein the first dielectric layer is formed directly on the first electrically conductive layer by condensation of a vaporized liquid; and
wherein the second dielectric layer is formed directly on the first dielectric layer, the second dielectric layer not being formed by condensation of a vaporized liquid.

2. A multilayer film, comprising:
first and second electrically conductive layers separated by at least first and second dielectric layers, wherein the first electrically conductive layer has at least one of an average surface roughness of at least ten nanometers, or a thickness of at least ten micrometers;
wherein the first dielectric layer comprises a polymer and is disposed on the first electrically conductive layer; and
wherein the second dielectric layer comprises a ceramic and is disposed on the first dielectric layer.

3. The multilayer film of claim 2, wherein both the first electrically conductive layer and the second electrically conductive layer have a thickness of at least 10 micrometers.

4. The multilayer film of claim 2, wherein the first and second electrically conductive layers comprise metal.

5. The multilayer film of claim 4, wherein the first electrically conductive layer is a metal foil.

6. The multilayer film of claim 2, wherein the second electrically conductive layer is a metal layer electroplated on the second dielectric layer.

7. The multilayer film of claim 2, wherein substantial portions of each two neighboring layers in the multilayer film are in physical contact with each other.

8. A multilayer dielectric film, comprising:
a first dielectric layer comprising a first material having a first breakdown field strength; and
a second dielectric layer formed directly on the first dielectric layer and comprising a second material having a second breakdown field strength less than the first breakdown field strength,
wherein the first dielectric layer has a third breakdown field strength at a localized position that is less than the second breakdown field strength, and wherein the multilayer dielectric film has a fourth breakdown field strength at the localized position that is greater than the third breakdown field strength.

9. The multilayer dielectric film of claim 8, wherein the first dielectric layer is formed by a condensation of a vaporized liquid.

10. The multilayer dielectric film of claim 8, wherein the second dielectric layer is not formed by a condensation of a vaporized liquid.

11. The multilayer film of claim 2, wherein the first dielectric layer has a dielectric constant less than 20 and wherein the second dielectric layer has a dielectric constant more than 20.

12. The multilayer film of claim 2, wherein the first dielectric layer has a thickness of up to one micrometer.

13. The multilayer film of claim 2, wherein the second dielectric layer is formed by sputtering.

14. The multilayer film of claim 2, wherein the second dielectric layer has a thickness of up to one micrometer.

15. The multilayer film of claim 2, wherein the second dielectric layer comprises zirconia.

16. The multilayer film of claim 2, the multilayer film being flexible.

17. The multilayer film of claim 2, wherein the multilayer film comprises a plurality of alternating first and second dielectric layers.

18. The multilayer film of claim 15, wherein the second dielectric layer comprises yttria-stabilized zirconia.

19. The multilayer film of claim 2, wherein the average surface roughness of the first electrically conductive layer on which the first dielectric layer is formed is at least 10 nanometers.

20. The multilayer film of claim 1, wherein the multilayer film comprises a plurality of alternating first and second dielectric layers.
